(19) United States
(12) Patent Application Publication
(10) Pub. No.: US 2006/0001928 A1
(43) Pub. Date: Jan. 5, 2006

(54) Image data processing of color image

(76) Inventor: Ikuo Hayaishi, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/159,874

(22) Filed: Jun. 22, 2005

(30) Foreign Application Priority Data
Jun. 25, 2004 (JP) 2004-187291

(51) Int. Cl. G03F 3/08

(52) U.S. Cl. 358/518

(57) ABSTRACT

This arrangement of the invention makes intuitively comprehensible image correction of RGB color image data after conversion to HSI data in an intuitive HSI expression format, while ensuring no substantial change of the picture quality of a resulting color image by correction.

The technique of the invention analyzes an image consisting of sampling HSI data with regard to each of multiple memory colors, that is, flesh color, green, and sky blue, and sets color correction areas as object correction ranges and correction rate curves in the color correction areas in respective hue ranges of the multiple memory colors, based on the results of the image analysis. These settings are given in the form of a correction table. A correction rate curve set for, for example, the hue range of flesh color in the correction table corrects original hue data Horg of HSI data converted from RGB color image data with a fixed correction rate Δ h in a substantial color correction zone SkH2 to SkH3, while correcting the original hue data Horg of the HSI data with varying correction rates Δ h in a pre-zone SkH1 to SkH2 and in a post-zone SkH3 to SkH4 before and after the substantial color correction zone SkH2 to SkH3 in a preset color correction area SkH1 to SkH4. The correction rate curve does not make any correction for the original hue data Horg of the HSI data out of the preset color correction area SkH1 to SkH4.

### CLAIM OF PRIORITY

The present application claims priority from Japanese Application P2004-187291 filed on Jun. 25, 2004, the content of which is hereby incorporated by reference into this application.

### BACKGROUND OF THE INVENTION

1. Field of the Invention

The present invention relates to a technique of processing input color image data representing a color image.

2. Description of the Related Art

The recent rapid spread of digital still cameras and other diverse imaging devices ensures easy accessibility of images in the form of digital data. Color image data consists of three color component data of R, G, and B images corresponding to three primary colors of light. The digital still cameras and other imaging devices output RGB tone value data as color image data. Display monitors and printers receive these RGB tone value data and display and print color images based on the RGB tone value data.

Some specific colors, that is, flesh color, green, and sky blue generally have emphasized visual effects in a color image. The use easily identifies, for example, even a slightly reddish tint or a slightly dim tint on the flesh color in the color image, as well as even slight differences among greens and sky blues in the color image. The flesh color, green, and sky blue are memory colors that are visually recognizable in a distinctive manner from other colors. An intuitive correction technique is thus preferable for such memory colors in the color image.

An HSI expression format using hue H, saturation S, and intensity I naturally allows the hue H, the saturation S, and the intensity I of each color image to be more readily processed than a conventional RGB expression format. This HSI expression format is widely applied to the intuitive correction procedure. One proposed technique converts RGB image data representing a color image into HSI data in the HSI expression format and subsequently corrects the hue H, the saturation S, and the intensity I of the color image (for example, U.S. Pat. No. 3,194,341).

This prior art technique sequentially corrects the hue H, the saturation S, and the intensity I of the whole converted HSI data. This undesirably increases the processing load of correction and extends the total data processing time. This sequential correction of the hue H, the saturation S, and the intensity I may cause the results of the correction of the hue H to be affected by subsequent correction of the saturation S and the intensity I. This may cause the user to feel some oddness and strangeness in the picture quality of a resulting corrected color image.

### SUMMARY OF THE INVENTION

The object of the invention is thus to eliminate the drawbacks of the prior art techniques and to make intuitively comprehensible image correction of RGB color image data after conversion to HSI data in an intuitive HSI expression format, while ensuring no substantial change of the picture quality of a resulting color image by correction.

In order to attain at least part of the above and the other related objects, an image processing device of the invention inputs color image data representing a color image, and sets a color correction area as an object correction range and a degree of correction according to a correction rate curve in the color correction area with regard to each of multiple specific colors, for example, multiple memory colors of flesh color, green, and sky blue. The image processing device sets the color correction areas and the correction rate curves, based on expression of the color image data in respective hue ranges of the multiple specific colors.

In one preferable application, the image processing device converts sampling data extracted from the color image data into HSI data in an HSI expression format using hue H, saturation S, and intensity I, specifies expression of the converted HSI data, and sets the color correction areas and the correction rate curves based on the specified expression of the HSI data. This arrangement desirably decreases the processing data volume for specification of the color correction areas and the correction rate curves, thus effectively reliving the operation load.

The image processing device of the invention converts the whole input color image data in the specific format into HSI data in the HSI expression format. The image processing device then corrects the hue H, the saturation S, and the intensity I of the HSI data in the HSI expression format with correction rate curves set in respective color correction areas of the hue H, the saturation S, and the intensity I, with regard to each of the multiple specific colors. Subsequently, the image processing device reversely converts the corrected HSI data into color image data in the specific format. The reversely converted color image data are output to an output device, for example, a monitor display or a printer.

The technique of the invention converts color image data in the specific format into HSI data in the intuitive HSI expression format and subsequently corrects the converted HSI data. This conversion to the HSI data enables the user to intuitively follow the correction. Only the hue ranges of the multiple specific colors are the target of correction of the HSI data with regard to the hue H, the saturation, and the intensity I. Namely correction is not made over the whole hue range. This simple procedure desirably relives the load of the correction operation.

The multiple specific colors, flesh color, green, and sky blue, do not have any overlaps in the hue H of the HSI data in the HSI expression format. Correction with a correction rate curve set for the hue range of one specific color affects only the HSI data in a preset color correction area in the hue range of the specific color, while not affecting correction in other color correction areas in the hue ranges of the other specific colors. The prior art technique sequentially corrects the whole HSI data with regard to the hue H, the saturation S, and the intensity I. The results of the correction of the hue H may thus be affected by subsequent correction of the saturation S and the intensity I. The technique of the invention, however, does not need sequential correction of the whole HSI data with regard to the hue H, the saturation S, and the intensity I, thus ensuring no substantial change of the picture quality of a resulting color image by correction. The prior-art sequential correction technique requires multiple cycles of correction operation, while the technique of this invention requires only one cycle of correction operation. This desirably relieves the operation load.

One preferable embodiment of the image processing device of the invention corrects each of the hue H, the saturation S, and the intensity I of the HSI data in the HSI expression format with a corresponding correction rate curve, which sets a fixed correction rate in a substantial color correction zone in a center of a corresponding color correction area and gives smaller correction rates than the fixed correction rate in a pre-zone and in a post-zone before and after the substantial color correction zone in the color correction area. This arrangement desirably avoids any abrupt changes of the corrected HSI data across the boundaries of the respective color correction areas, thus effectively preventing the user from feeling some oddness and strangeness in the picture quality of a resulting corrected color image.

Another preferable embodiment of the image processing device of the invention specifies a variation of each correction rate curve in each color correction area as the object correction range to set a correction rate of 0 to a specific point of a hue value having best match with each of the multiple specific colors. The procedure of this embodiment does not make any correction at specific points of hue values having the best matches with the respective specific colors, flesh color, green, and sky blue, while making the correction for surrounding hue values around the respective specific points. This arrangement effectively prevents the user from feeling some oddness and strangeness in the picture quality of a resulting corrected color image with regard to these specific colors.

The image data processing technique of the invention is actualized by diversity of applications other than the image processing device, for example, a corresponding image data processing method, computer programs that cause a computer to attain the functions of the image processing device or the corresponding image data processing method, and recording media that store such computer programs.

### BRIEF DESCRIPTION OF THE DRAWINGS

FIG. 1 schematically illustrates the configuration of an image processing system in one embodiment of the invention;

FIG. 2 is a flowchart showing an image editing process to correct color image data input by an image data input unit of the image processing system;

FIG. 3 shows RGB image data in an orthogonal coordinates system of R, G, and B axes as orthogonal axes;

FIG. 4 conceptually shows hue H, saturation S, and intensity I in an HSI hex-cone color model;

FIG. 5 conceptually shows a process of manipulating the hue H and the saturation S in the HSI hex-cone color model;

FIG. 6 shows one example of image analysis based on sampling HSI data;

FIG. 7 shows an object correction range (color correction area) set based on results of image analysis;

FIG. 8 shows a correction table including the settings of color correction areas and correction rates in the respective color correction areas based on the results of the image analysis;

FIG. 9 is a map showing correction rate curves as a different visual representation of the correction table of FIG. 8; and

FIG. 10 shows a correction rate curve in a hue range of flesh color in a modified correction table.

### DESCRIPTION OF THE PREFERRED EMBODIMENTS

In order to clarify the features, aspects, and effects of the invention, one mode of carrying out the invention is described below as a preferred embodiment in the following sequence:
A. Embodiment
   A1. Configuration of Image Processing System
   A2. Image Editing Process
   A3. Modified Image Editing Process

### A. Embodiment

A1. Configuration of Image Processing System

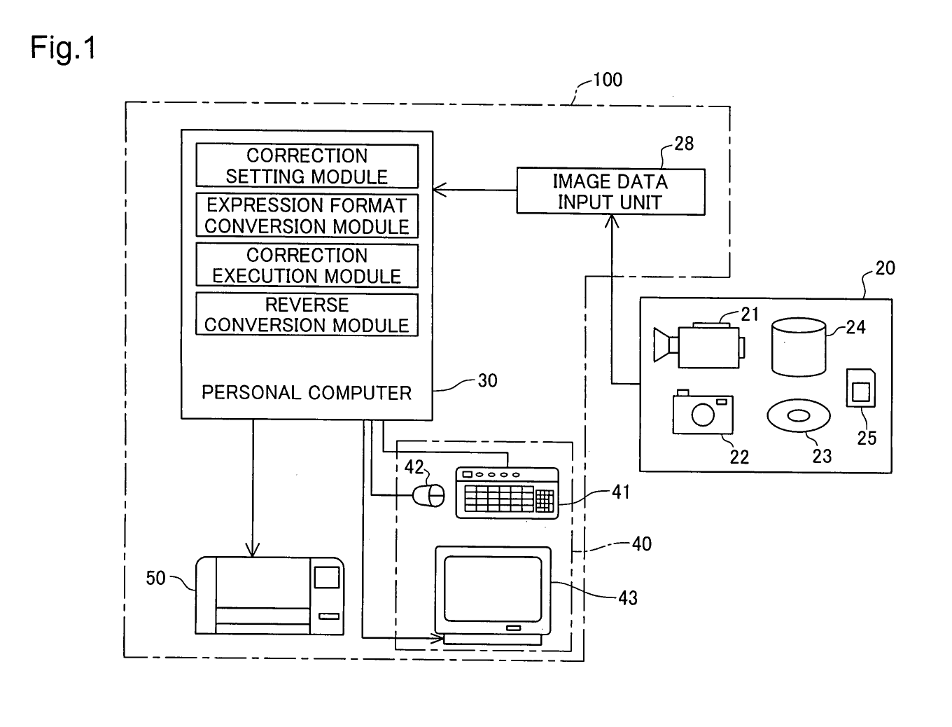

FIG. 1 schematically illustrates the configuration of an image processing system 100 in one embodiment of the invention. As illustrated, the image processing system 100 includes a personal computer 30 as a primary device, user interfaces 40 operated by the user to instruct a required series of image editing process, and a color printer 50 used to output edited images. An image data input unit 28 inputs image data from an image database 20, which supplies various image data representing moving images and still images, and transfers the input image data to the personal computer 30. The personal computer 30 stores the input image data into non-illustrated memory units, such as internal memories and a hard disk.

The image database 20 includes various imaging devices, such as a digital video camera 21 and a digital still camera 22, and diverse image data storage units, such as a DVD 23, a hard disk 24, and a memory card 25, and supplies image data to the personal computer 30. The DVD 23, the hard disk 24, and the memory card 25 store color image data representing color still images taken by the imaging device, for example, the digital still camera 22. The color image data are constructed as R, G, and B tone value data of R, G, and B images corresponding to three primary colors of light.

The personal computer 30 is designed to output edited color images as RGB tone value data to the color printer 50 and a display 43 of the user interfaces 40, as discussed later.

The personal computer 30 includes a CPU, a ROM, a RAM, and a hard disk with image processing software installed therein, although these constituents are not specifically illustrated. These constituents cooperatively exert required functions for image processing, that is, a correction setting module, an expression format conversion module, a correction execution module and a reverse conversion module. The personal computer 30 receives and sends data from and to the external devices, such as the image data input unit 28, the display 43, and the color printer 50, via non-illustrated I/F circuits. The image processing software installed in the hard disk is executed to correct color image data input by the image data input unit 28. The details of this image processing flow (image editing process) will be described below. The image data input unit 28 may be incorporated in the personal computer 30.

A2. Image Editing Process

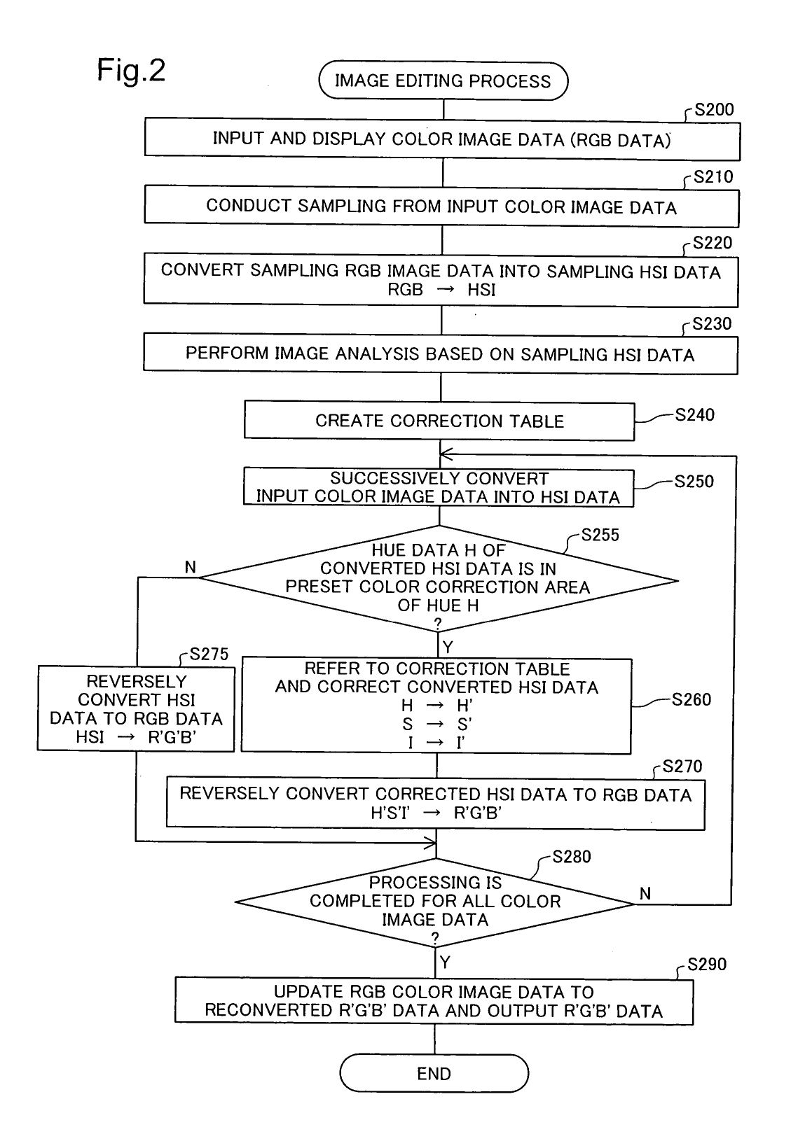

FIG. 2 is a flowchart showing an image editing process to correct color image data input by the image data input unit 28.

The image editing process (image data processing) of FIG. 2 is triggered by the user's predetermined operation, for example, the user's press of a certain switch (not shown) or the user's key operation on a keyboard 41 included in the user interfaces 40 in the image processing system 100 having the hardware configuration discussed above. The image editing process may otherwise be executed in response to the user's click of an image editing start icon on the screen of the display 43 with a mouse 42 as one of the user interfaces 40.

In the image editing process, the personal computer 30 first inputs color image data of each color image as a possible option of an editing object from the image database 20, for example, the digital still camera 22 or the memory card 25, via the image data input unit 28 and shows a color image expressed by the input color image data (RGB data) on the display 43 (step S200). The color image data are RGB data corresponding to three primary colors and have RGB tone values of individual pixels.

When simultaneous input of image data representing multiple images is allowed, a list of the simultaneously input images may be displayed as thumbnail images, for example, in a right-half display area on the display 43. The display of the simultaneously input multiple images may otherwise be sequentially switched on the display 43. The user selects an object image to be edited among the displayed multiple images through the keyboard operation and the mouse operation. The personal computer 30 waits for the user's selection of the object image. In the case of input of image data representing only one image, however, the personal computer 30 does not wait for the user's operation but immediately displays the input image on the display 43 at step S200.

The user may select object image data out of a list of the names of image data, instead of the displayed images.

The personal computer 30 conducts sampling and extraction from the input color image data according to a predetermined rule (step S210). The sampling technique is not specifically restricted but may be adequately selected according to the operation load of image analysis (discussed later) and other relevant factors. For example, the sampling process may perform sampling and extraction from color image data in a (m×n) matrix to a data volume of 1/100 to 1/1000 of the total data volume. Typical sampling techniques applicable here include systematic sampling, random sampling, and importance sampling.

The personal computer 30 converts the extracted sampling RGB image data into HSI sampling data expressed in an HSI format called an HSI hex-cone color model (step S220). The hex-cone color model is used to convert image data expressed by R, G, and B tone values into another expression format of the hue H, the saturation S, and the intensity I. The HSI hex-cone color model is widely applied as a technique of simply and intuitively manipulating an image in terms of the hue H, the saturation S, and the intensity I. The outline of data conversion by the HSI hex-cone color model is described below.

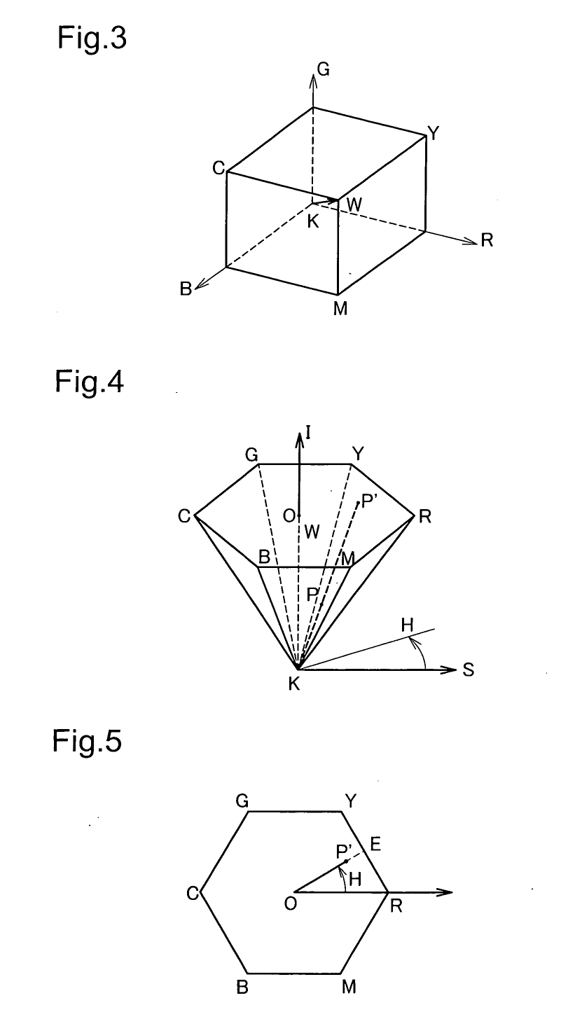

FIG. 3 shows RGB image data in an orthogonal coordinates system of R, G, and B axes as orthogonal axes. FIG. 4 conceptually shows the hue H, the saturation S, and the intensity I in the HSI hex-cone color model. FIG. 5 conceptually shows a process of manipulating the hue H and the saturation S in the HSI hex-cone color model.

The RGB image data is tone data and is expressible as a point in a cube (color solid) of 255 on each side when the available tone value range is 0 to 255. For example, image data of black (K) has R, G, and B tone values all equal to 0 and is thus expressible as an apex having coordinates (0,0,0). Image data of white (W) has R, G, and B tone values all equal to 255 and is thus expressible as an apex having coordinates (255,255,255). Similarly red (R), green (G), and blue (B) are respectively expressible as apexes having coordinates (255,0,0), (0,255,0), and (0,0,255). Cyan (C) complementary to red (R) is expressible as an apex of coordinates (0,255,255) that faces the apex of red (R). Magenta (M) complementary to green (G) is expressible as an apex of coordinates (255,0,255) that faces the apex of green (G). Yellow (Y) complementary to blue (B) is expressible as an apex of coordinates (255,255,0) that faces the apex of blue (B).

The HSI hex-cone color model sets a K-W axis of the color solid to an axis I, projects the respective coordinates of the color solid on a plane perpendicular to the axis I, and computes the saturation S and the hue H of image data on the projected plane. The intensity I is directly computable from the coordinates of the color solid. For example, the intensity I of given image data (R,G,B) is computed according to Equation (1):
I=max(R,G,B) (1)
where max(R,G,B) represents a function of selecting the maximum among the R, G, and B tone data. When the image data (R,G,B) is given as a point P in the color solid, the saturation S and the hue H are computed from the coordinates of a projected point P′, which is set by projection of the point P on the plane perpendicular to the axis I as shown in FIG. 4.

Projection on the plane perpendicular to the axis I converts the apexes R, Y, G, C, M, and B of the color solid to apexes of a regular hexagon and the apexes K and W of the color solid to a center O of the regular hexagon, as shown in FIG. 5. As clearly understood from this projection, in the HSI hex-cone color model, the center O of the regular hexagon expresses achromatic color. The saturation S increases with an increase in distance from the center O and reaches the maximum on the circumference of the regular hexagon. The saturation S is expressible as a ratio of (length of a line segment OP′) to (length of a line segment OE), where a point E represents an intersection of a line going through the projected point P′ and the center O with the circumference of the regular hexagon as shown in FIG. 5. The saturation S is computed from the RGB image data of the point P according to Equation (2):
S=255(1−i)/I (2)
where i=min(R,G,B), which represents a function of selecting the minimum among the R, G, and B tone data, and I denotes the intensity I computed by Equation (1) given above. As clearly shown by Equation (2), the saturation S is indefinite for the intensity I=0.

Projection of the apexes R, Y, G, C, B, and M of the color solid to the apexes R, Y, G, C, B, and M of the regular hexagon shown in FIG. 5 proves that the hue H is expressible by an angle of a line segment OR and the line segment OP′ in the HSI hex-cone color model. The hue H is computed from the RGB image data of the point P according to one of Equations (3) to (5) given below:

when R=I,
H=255(b−g)/6 (3)
when G=I,
H=255(2+r−b)/6 (4)
when B=I,
H=255(4+g−r)/6 (5)
where r=(I−R)/(I−i)
g=(I−G)/(I−i)
b=(I−B)/(I−i)
When the computed value H<0, 255 is to be added to the computed value H.

The image editing process of FIG. 2 applies the HSI hex-cone color model to compute the hue H, the saturation S, and the intensity I from the R, G, and B tone data of the sampling RGB image data according to Equations (1) through (5) given above at step S220. The R, G, and B tone data of the sampling RGB image data in the tone value range of 0 to 255 are accordingly converted to the saturation S, the hue H, and the intensity I in the value range of 0 to 255. The hue H is expressed by the rotational angle from the axis of the saturation S as clearly shown in FIGS. 4 and 5. The above tone value expression may thus be replaced by the angle expression from the axis of the saturation S. The saturation S and the intensity I may be shown by percentage (%) relative to the tone value 255 converted to 1.

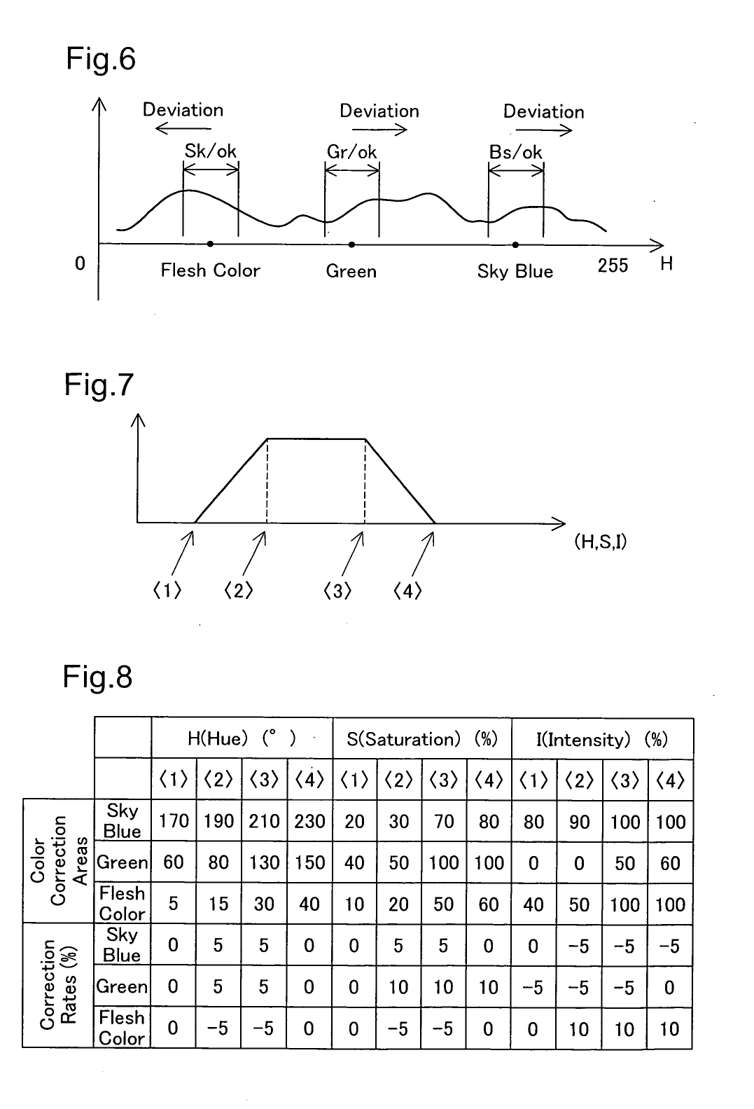

The personal computer 30 then performs image analysis based on the converted sampling HSI data (step S230). The image analysis sets distributions of the sampling HSI data of the analyzed image with regard to specific memory colors, that is, flesh color, green, and sky blue, which are memorable because of the visual characteristics. FIG. 6 shows one example of image analysis based on sampling HSI data.

Because of the characteristics of the HSI hex-cone color model, the hue H does not have any overlap among hue ranges of the specific memory colors, that is, flesh color, green, and sky blue. A distribution of the sampling HSI data with regard to the hue H is shown in FIG. 6. The distribution of FIG. 6 includes a flesh color hue range Sk/ok attaining the sufficient visual representation of flesh color, a green hue range Gr/ok attaining the sufficient visual representation of green, and a sky blue hue range Bs/ok attaining the sufficient visual representation of sky blue.

In the distribution of the sampling HSI data, when the actual hue range of flesh color in the analyzed color image is substantially equal to or mostly overlaps the flesh color hue range Sk/ok, the visual representation of flesh color sufficiently looks flesh color in the color image. In the illustrated distribution of FIG. 6, the sampling HSI data is deviated toward the hue H=0 from the flesh color hue range Sk/ok. The image analysis thus gives a rather reddish visual representation of flesh color. The image analysis similarly has some deviations with regard to the other memory colors, green and sky blue.

The saturation S and the intensity I of the specific memory colors, that is, flesh color, green, and sky blue, have some overlaps in the respective hue ranges. The sampling HSI data gives distributions of the saturation S and the intensity I in the respective hue ranges of these specific memory colors. The image analysis thus enables detection of insufficiencies and excesses of the saturation S and the intensity I.

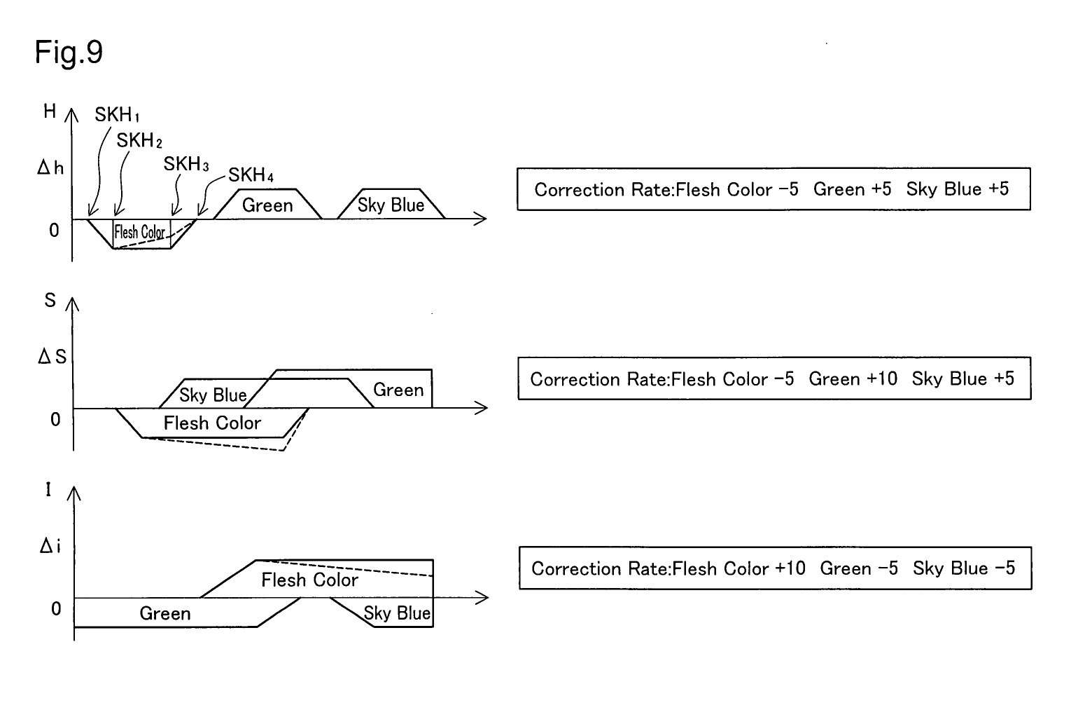

The personal computer 30 sets a color correction area as an object correction range and a correction rate curve in the color correction area with regard to each of the hue H, the saturation S, and the intensity I in each of the hue ranges of the specific memory colors, that is, flesh color, green, and sky blue, based on the results of the image analysis, so as to complete a correction table including such settings (step S240). FIG. 7 shows an object correction range (color correction area) set based on the results of the image analysis. FIG. 8 shows a correction table including the settings of color correction areas and correction rates in the respective color correction areas based on the results of the image analysis. FIG. 9 is a map showing correction rate curves as a graphical representation of the correction table of FIG. 8.

At step S240 in the flowchart of FIG. 2, the personal computer 30 first sets a color correction area with regard to each of the hue H, the saturation S, and the intensity I in each of the hue ranges of the specific memory colors, that is, flesh color, green, and sky blue. A concrete procedure sets a lower limit <2> and an upper limit <3> of a substantial color correction zone, as well as a starting point <1> and an end point <4> respectively related to the lower limit <2> and the upper limit <3> as shown in FIG. 7. This specifies each color correction area, which includes the substantial color correction zone between the lower limit <2> and the upper limit <3>, a pre-zone between the starting point <1> and the lower limit <2>, and a post-zone between the upper limit <3> and the end point <4>. The personal computer 30 subsequently sets a correction rate curve in the color correction area. The concrete procedure sets a fixed correction rate for the substantial color correction zone between the lower limit <2> and the upper limit <3>, and specifies correction rates at the starting point <1> and at the end point <4> to determine correction rate variations in the pre-zone between the starting point <1> and the lower limit <2> and in the post-zone between the upper limit <3> and the end point <4>. FIG. 9 shows color correction areas and their correction rate curves with regard to the hue H, the saturation S, and the intensity I in the respective hue ranges of the specific memory colors, that is, flesh color, green, and sky blue.

After creation of the correction table as shown in FIGS. 8 and 9, the personal computer 30 successively converts the input color image data into HSI data in the HSI expression format (step S250) by the procedure described above. The personal computer 30 subsequently determines whether the hue data H of the converted HSI data is included in a preset color correction area of the hue H shown in FIG. 9 (step S255). When it is determined at step S255 that the hue data H of the converted HSI data is out of the color correction area of the hue H, the image editing routine goes to step S275 to convert reversely the HSI data to RGB image data (R′,G′,B′) in the original RGB format without any correction.

When it is determined at step S255 that the hue data H of the converted HSI data is within the color correction area of the hue H, on the other hand, the personal computer 30 refers to the correction table of FIGS. 8 and 9 and corrects the converted HSI data (step S260). The concrete procedure of correction is described below with reference to a correction rate curve of the hue H in the correction table of FIGS. 8 and 9.

In the illustrated example of FIG. 9, the starting point <1>, the lower limit <2>, the upper limit <3>, and the end point <4> are respectively set to SkH1, SkH2, SkH3, and SkH4 in the hue range of flesh color. The hue data H of the converted HSI data (step S250) is expressed as Horg, and the hue data H′ of the corrected HSI data (step S260) is expressed as H′dh. When the original hue data Horg is out of a preset color correction area defined by SkH1 through SkH4, the processing flow skips the correction operation in response to a negative answer at step S255 and directly sets the corrected hue data H′dh equal to the original hue data Horg. A correction rate Δ h set in the correction table is equal to 0 in this case. The corrected hue data H′dh is accordingly equal to Horg even when the decision of step S255 is omitted.

When the original hue data Horg is within the preset color correction area defined by SkH1 through SkH4, on the other hand, the original hue data Horg is corrected with a preset correction rate curve Δ h to give the corrected hue data H′dh =(1+Δ h) Horg. The correction rate curve Δ h for correction of Horg to H′dh gives a fixed value in a substantial color correction zone between SkH2 and SkH3 and varying values in a pre-zone between SkH1 and SkH2 and in a post-zone between SkH3 and SkH4.

The hue H is corrected with the correction rate curve Δ h set in the correction table of FIGS. 8 and 9, when the hue data H of the converted HSI data (step S250) is included in the hue range of flesh color. Such corrections of the hue H, the saturation S, and the intensity I are made in the respective hue ranges of flesh color, green, and sky blue. Namely no corrections of the hue H, the saturation S, and the intensity I are made when the hue data H of the converted HSI data is out of any hue ranges of flesh color, green, and sky blue.

Subsequently, the personal computer 30 reversely converts the corrected HSI data (having corrected hue H′, corrected saturation S′, and corrected intensity I′) to RGB image data (R′,G′,B′) in the original RGB format (step S270), and determines whether processing has been completed with regard to all the input color image data (step S280). When there is any unprocessed color image data, the processing of steps S250 to S280 is repeated. When all the input color image data have been processed, the personal computer 30 updates the RGB image data input at step S200 to the reversely converted RGB image data (R′,G′,B′) and outputs the updated RGB image data (R′,G′,B′) to the display 43 or to the color printer 50 (step S290). The display 43 shows a resulting color image based on the reversely converted RGB image data (R′,G′,B′), whereas the color printer 50 prints and outputs a resulting color image based on the reversely converted RGB image data (R′,G′,B′).

The reversely converted RGB image data (R′,G′,B′) output at step S290 include the corrected and reversely converted RGB image data (R′,G′,B′) (steps S260 and S270) and the uncorrected and reversely converted RGB image data (R′,G′,B′) (step S275). Since no correction is made, the latter data are identical with the original RGB image data.

As described above, the procedure of the embodiment converts RGB color image data, which represents a color image input from, for example, the digital still camera 22, into HSI data in the intuitive HSI expression format and subsequently corrects the converted HSI data. This conversion to the HSI data enables the user to intuitively follow the correction. Only the hue ranges of flesh color, green, and sky blue are the target of correction of the HSI data with regard to the hue H, the saturation, and the intensity I. Namely correction is not made over the whole hue range. The correction object is the HSI data having the hue H in the preset color correction area (SkH1 to SkH4) of flesh color, the preset color correction areas of green, and the preset color correction area of sky blue shown in FIG. 9. The procedure of this embodiment does not need sequential correction of the whole HSI data with regard to the hue H, the saturation S, and the intensity I, but requires only one cycle of correction for the specified part of the HSI data. This simple procedure desirably relives the load of the correction operation.

These specific memory colors, flesh color, green, and sky blue, do not have any overlaps in the hue H of the HSI data in the intuitive HSI expression format. Correction with the correction rate curve set for the hue range of flesh color affects only the HSI data in the preset color correction area SkH1 to SkH4 in the hue range of flesh color. As mentioned above, the procedure of this embodiment does not need sequential correction of the whole HSI data with regard to the hue H, the saturation S, and the intensity I. These combined effects ensure no substantial change of the picture quality of a resulting color image by correction.

The color correction table of FIGS. 8 and 9 is created by specifying the color correction areas and the correction rate curves of the HSI data converted from sampling RGB image data. This method desirably decreases the processing data volume for specification of the color correction areas and the correction rate curves, thus effectively reliving the operation load.

In the color correction table of this embodiment shown in FIGS. 8 and 9, each correction rate curve applied to correction of the HSI data has an increase in a pre-zone (for example, SkH1 to SkH2 in the hue range of flesh color) and a decrease in a post-zone (SkH3 to SkH4) before and after a fixed correction rate in a substantial color correction zone (SkH2 to SkH3). This arrangement desirably avoids an abrupt change of the corrected HSI data and effectively prevents the user from feeling some oddness and strangeness in the picture quality of a resulting corrected color image, for example, due to abrupt changes of the hue, the saturation, and the intensity on the boundaries between the hue range of flesh color and adjacent hue ranges.

The procedure of the embodiment sets fixed values to correction rates Δ h, Δ s, and Δ i in respective substantial color correction zones of the hue H, the saturation S, and the intensity I in the hue range of flesh color. As shown by the broken lines in FIG. 9, the correction rate curves Δ h, Δ s, and Δ I may be varied in these substantial color correction zones. The variations may be set based on the results of image analysis at step S230.

A3. Modified Image Editing Process

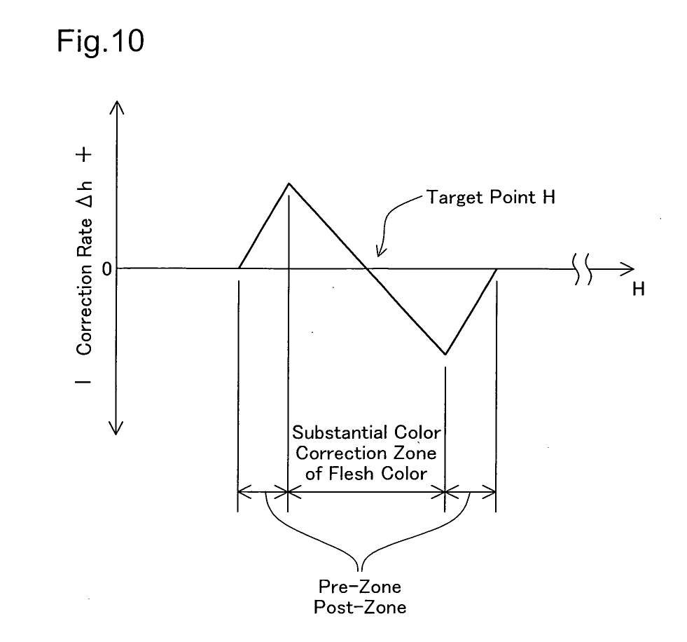

The correction table created at step S240 in the flowchart of FIG. 2 may have a modification. The primary characteristic of this modification selects a value of HSI data having the best match in visual recognition with flesh color, green, or sky blue as a target point and sets the correction rate of the target point to 0. FIG. 10 shows a correction rate curve in the hue range of flesh color in the modified correction table.

In the modified correction table of FIG. 10, the correction rate curve intersects with the hue axis H and is equal to 0 at the target point included in the substantial color correction zone between the lower limit <2> and the upper limit <3> (see FIG. 7) in the hue range of flesh color. The starting point <1> and the end point <4> are set in relation to the lower limit <2> and the upper limit <3> as described in the embodiment. The variations of the correction rate curve in pre-zone between the starting point <1> and the lower limit <2>, the substantial color correction zone between the lower limit <2> and the upper limit <3>, and the post-zone between the upper limit <3> and the end point <4> are set based on the results of image analysis at step S230 in the flowchart of FIG. 2.

The modified correction rate curve keeps the HSI data unchanged at the target point with no correction. The absolute value of the correction rate gradually decreases from the lower limit <2> to the target point and gradually increases from the target point to the upper limit <3> in the substantial color correction zone. Such correction curves are obtained with regard to the hue H, the saturation S, and the intensity I in the respective hue ranges of flesh color, green, and sky blue.

The modified procedure sets the correction rate of the HSI data to 0 at the target point having the best match in visual recognition with flesh color, green, or sky blue. The HSI data at the target point accordingly represents a corresponding target color having the best match in visual recognition with flesh color, green, or sky blue. The correction rate curve gives the smaller value to the hue range closer to the target color. There is accordingly no abrupt change across the target color. The correction rate curve gives the larger value to the hue range apart from the target color. Such correction desirably improves the expression of the target color and expands the expression range of the target color and thus effectively prevents the user from feeling some oddness and strangeness in the picture quality of a resulting color image.

The embodiment and its modification discussed above are to be considered in all aspects as illustrative and not restrictive. There may be many other modifications, changes, and alterations without departing from the scope or spirit of the main characteristics of the present invention.

The procedure of the above embodiment converts the sampling RGB image data into HSI data in the intuitive HSI expression format and subsequently sets color correction areas and correction rate curves for the HSI data. One modified procedure may set color correction areas and correction rate curves for the sampling RGB image data without conversion. The object color space for correction is not limited to the HSI color space, but may be any color space equivalent to the HSI color space, for example, HSB, HSV, and L*a*b* color spaces.

Having described a preferred embodiment of the invention with reference to the accompanying drawings, it is to be understood that the invention is not limited to the embodiments, and that various changes and modifications could be effected therein by one skilled in the art without departing from the spirit or scope of the invention as defined in the appended claims.

What is claimed is:

1. An image processing device that processes color image data representing a color image in a specific format, said image processing device comprising:
a correction setting module that sets a color correction area as an object correction range and a degree of correction in the color correction area with regard to each of multiple specific colors;
an expression format conversion module that converts the color image data in the specific format into color component data in a color component expression format using predetermined color components, hue, saturation, and lightness;
a correction execution module that corrects the hue, the saturation, and the lightness of the color component data in the color component expression format with the degrees of correction set in respective color correction areas of the hue, the saturation, and the lightness, with regard to each of the multiple specific colors; and
a reverse conversion module that reversely converts the corrected color component data into color image data in the specific format.

2. An image processing device in accordance with claim 1, wherein said correction setting module sets the degree of correction according to a correction curve in the color correction area with regard to each of multiple specific colors.

3. An image processing device in accordance with claim 2, wherein said expression format conversion module converts the color image data in the specific format into HSI data in an HSI expression format using hue H, saturation S, and intensity I,
said correction execution module corrects the hue H, the saturation S, and the intensity I of the HSI data in the HSI expression format with correction rate curves set in respective color correction areas of the hue H, the saturation S, and the intensity I, with regard to each of the multiple specific colors, and
said reverse conversion module reversely converts the corrected HSI data into color image data in the specific format.

4. An image processing device in accordance with claim 3, wherein the multiple specific colors include flesh color, green, and sky blue.

5. An image processing device in accordance with claim 3, wherein said correction setting module sets the color correction areas and the correction rate curves, based on expression of the color image data in respective hue ranges of the multiple specific colors.

6. An image processing device in accordance with claim 5, wherein said correction setting module converts sampling data extracted from the color image data into HSI data in the HSI expression format, specifies expression of the converted HSI data, and sets the color correction areas and the correction rate curves based on the specified expression of the HSI data.

7. An image processing device in accordance with claim 3, wherein said correction execution module corrects each of the hue H, the saturation S, and the intensity I of the HSI data in the HSI expression format with a corresponding correction rate curve, which sets a fixed correction rate in a substantial color correction zone in a center of a corresponding color correction area and gives smaller correction rates than the fixed correction rate in a pre-zone and in a post-zone before and after the substantial color correction zone in the color correction area.

8. An image processing device in accordance with claim 3, wherein said correction setting module specifies a variation of each correction rate curve in each color correction area as the object correction range to set a correction rate of 0 to a specific point of a hue value having best match with each of the multiple specific colors.

9. An image data processing method that processes color image data representing a color image in a specific format, said image data processing method comprising the steps of:
(a) setting a color correction area as an object correction range and a correction rate curve in the color correction area with regard to each of multiple specific colors;
(b) converting the color image data in the specific format into HSI data in an HSI expression format using hue H, saturation S, and intensity I;
(c) correcting the hue H, the saturation S, and the intensity I of the HSI data in the HSI expression format with correction rate curves set in respective color correction areas of the hue H, the saturation S, and the intensity I, with regard to each of the multiple specific colors;
(d) reversely converting the corrected HSI data into color image data in the specific format; and
(e) outputting the reversely converted color image data in the specific format.

10. A computer program product that causes a computer to execute a series of image processing that processes color image data representing a color image in a specific format,
said computer program product comprising:
a computer readable medium; and
a computer program stored on said computer readable medium,
said computer program comprising:
(a) a first program code that sets a color correction area as an object correction range and a correction rate curve in the color correction area with regard to each of multiple specific colors;
(b) a second program code that converts the color image data in the specific format into HSI data in an HSI expression format using hue H, saturation S, and intensity I;
(c) a third program code that corrects the hue H, the saturation S, and the intensity I of the HSI data in the HSI expression format with correction rate curves set in respective color correction areas of the hue H, the saturation S, and the intensity I, with regard to each of the multiple specific colors;
(d) a fourth program code that reversely converts the corrected HSI data into color image data in the specific format; and
(e) a fifth program code that outputs the reversely converted color image data in the specific format.
